(19) United States
(12) Patent Application Publication
(10) Pub. No.: US 2026/0075796 A1
(43) Pub. Date: Mar. 12, 2026

(54) MEMORY AND MANUFACTURING METHOD THEREFOR, AND ELECTRONIC DEVICE

(71) Applicant: CXMT Corporation, Hefei City (CN)

(72) Inventors: Chao LIN, Hefei City (CN); Wenjing CHEN, Hefei City (CN)

(73) Assignee: CXMT Corporation, Hefei City (CN)

(21) Appl. No.: 19/393,073

(22) Filed: Nov. 18, 2025

Related U.S. Application Data
(63) Continuation of application No. PCT/CN2024/100566, filed on Jun. 21, 2024.

(30) Foreign Application Priority Data
Dec. 25, 2023 (CN) 202311804212.0

(51) Int. Cl. H10B 12/00

(52) U.S. Cl. CPC H10B 12/30; H10B 12/02

(57) ABSTRACT

The present disclosure provides a memory and a manufacturing method therefor, and an electronic device. The memory includes multiple bit line functional groups, multiple storage units, and a staircase structure, and each of the bit line functional groups includes a first bit line structure, multiple second bit line structures, and multiple selection transistors. The first bit line structure includes a first isolation layer and a first bit line circumferentially surrounding the first isolation layer. Multiple second bit line structures are provided on a first side of the first bit line in a third direction, a staircase structure is provided on a second side of the first bit line in the third direction, and multiple conductive stairs of the staircase structure are respectively coupled to corresponding first bit lines.

### CROSS-REFERENCE TO RELATED APPLICATIONS

This is a continuation application of International Patent Application No. PCT/CN2024/100566 filed on Jun. 21, 2024, which claims priority to Chinese Patent Application No. 202311804212.0 filed on Dec. 25, 2023. The disclosures of the above-referenced applications are hereby incorporated by reference in their entirety.

### TECHNICAL FIELD

The present disclosure relates to the field of semiconductor technologies, and in particular, to a memory and a manufacturing method therefor, and an electronic device.

### BACKGROUND

As semiconductor technologies and storage technologies continuously develop, electronic devices are continuously developing towards miniaturization and integration. A dynamic random access memory (Dynamic Random Access Memory, DRAM for short) is widely applied in various electronic devices because the memory has relatively high storage density and a relatively fast read/write speed.

The dynamic random access memory includes a word line (Word Line, WL for short), a bit line (Bit Line, BL for short), and multiple storage units. Each storage unit generally includes an access transistor and a capacitor. The gate of the access transistor is electrically connected to the word line, one of the source and the drain is electrically connected to the bit line, and the other of the source and the drain is electrically connected to the capacitor. A voltage on the word line can control the access transistor to be turned on or off, allowing data information in the capacitor to be read through the bit line, or data information to be written into the capacitor.

To improve storage density, the bit line generally includes a common bit line and a local bit line, and the local bit line is correspondingly coupled to the storage unit. The common bit line is coupled to the local bit line through a selection transistor, and is externally connected through a staircase structure. However, in a manufacturing procedure of the bit line, the common bit line is easily disconnected, and memory performance is relatively poor.

### SUMMARY

In view of the foregoing problem, embodiments of the present disclosure provide a memory and a manufacturing method therefor, and an electronic device, to improve performance of the memory.

According to some embodiments, the present disclosure provides a memory. The memory includes multiple bit line functional groups arranged at intervals in a first direction, multiple storage units, and a staircase structure. Each of the bit line functional groups includes: a first bit line structure, the first bit line structure including a first isolation layer extending in a second direction and a first bit line circumferentially surrounding the first isolation layer; multiple second bit line structures, the multiple second bit line structures being located on a first side of the first bit line in a third direction and arranged at intervals in the second direction, each of the second bit line structures including a second bit line, and any two of the second direction, the third direction, and the first direction intersecting each other; and multiple selection transistors, the multiple selection transistors being located between the first bit line structure and the multiple second bit line structures, and second bit lines in the multiple second bit line structures being respectively coupled to the first bit line through the multiple selection transistors. The multiple storage units are respectively coupled to corresponding second bit lines. The staircase structure is located on a second side of the first bit line in the third direction and including multiple conductive stairs, and the multiple conductive stairs are respectively coupled to first bit lines in the multiple bit line functional groups.

In some possible implementations, the first bit line in at least one of the bit line functional groups includes a first bit line portion and a second bit line portion. The first bit line portion is in the non-closed ring shape, and an opening of the non-closed ring shape is located on a second side of the first bit line structure in the third direction. The second bit line portion is located at the opening of the non-closed ring shape and the second bit line portion has the same material composition as the conductive stairs.

In some possible implementations, first bit lines in some of the bit line functional groups each include the first bit line portion and the second bit line portion, and first bit lines in remaining bit line functional groups are each in a closed ring shape; and each of the second bit line structures further includes a second isolation layer extending in the third direction, and the second bit line circumferentially surrounds the second isolation layer.

In some possible implementations, the second isolation layer has the same material composition as the first isolation layer, and the first bit line portion has the same material composition as the second bit line.

In some possible implementations, first isolation layers that are opposite in the first direction are connected to form an integral structure, and first bit lines that are opposite in the first direction are spaced apart from each other; and second isolation layers that are opposite in the first direction are connected to form an integral structure, and second bit lines that are opposite in the first direction are spaced apart from each other.

In some possible implementations, the multiple storage units are arranged at intervals in the first direction, arranged at intervals in the second direction, and arranged at intervals in the third direction, and each of the second bit line structures is correspondingly provided with the storage unit on at least one side in two opposite sides of the each of the second bit line structures in the second direction.

In some possible implementations, each of the storage units includes an access transistor and a capacitor that are coupled, the access transistor is correspondingly coupled to the second bit line structure, and the capacitor is disposed on a side, away from the corresponding second bit line structure, of the access transistor.

In some possible implementations, the selection transistor and the access transistor each include a gate, a gate dielectric layer surrounding the gate, and an active layer surrounding the gate dielectric layer; and gates that are opposite in the first direction are connected to form a word line, gate dielectric layers that are opposite in the first direction are connected to form an integrated structure, and active layers that are opposite in the first direction are spaced apart from each other and coupled to the corresponding second bit line structures.

In some possible implementations, the capacitor includes a first electrode, a capacitor dielectric layer surrounding the first electrode, and a second electrode surrounding the capacitor dielectric layer; and first electrodes that are opposite in the first direction are connected to form an integral structure, capacitor dielectric layers that are opposite in the first direction are connected to form an integral structure, and second electrodes that are opposite in the first direction are spaced apart from each other and coupled to the corresponding active layers.

In some possible implementations, each of the conductive stairs has a groove, the groove separates the corresponding conductive stair into a first segment and a second segment that are spaced apart in the second direction, the grooves are communicated, and each of the grooves has a first end and a second end that are opposite in the second direction; and in any three adjacent grooves in the first direction, a first end of a groove located in the middle is opposite to a first end of one of remaining two grooves, a second end of the groove located in the middle is opposite to a second end of the other of the remaining two grooves, so that first segments in every other row form a first staircase, second segments in every other row form a second staircase, stair surfaces of the first staircase and stair surfaces of the second staircase are staggered in the first direction, and the first staircase and the second staircase form the staircase structure.

In some possible implementations, each of the conductive stairs has a first end and a second end that are opposite in the second direction; and in any three adjacent conductive stairs in the first direction, a first end of a conductive stair located in the middle is opposite to a first end of one of remaining two conductive stairs, a second end of the conductive stair located in the middle is opposite to a second end of the other of the remaining two conductive stairs, so that first ends of conductive stairs in every other row form a first staircase, second ends of conductive stairs in every other row form a second staircase, stair surfaces of the first staircase and stair surfaces of the second staircase are staggered in the first direction, and the first staircase and the second staircase form the staircase structure.

In some possible implementations, the memory further includes multiple filling patterns located on a first side of the first bit line in the third direction, and in the second direction, the multiple filling patterns are opposite to the multiple selection transistors, and at least one of the filling patterns is provided between two adjacent selection transistors.

The memory provided in the embodiments of the present disclosure have at least the following advantages:

The memory provided in the embodiments of the present disclosure includes multiple bit line functional groups, multiple storage units, and a staircase structure, and the multiple bit line functional groups are arranged at intervals in a first direction. Each of the bit line functional groups includes a first bit line structure, multiple second bit line structures, and multiple selection transistors. The first bit line structure includes a first isolation layer and a first bit line. The first isolation layer extends in a second direction, and the first bit line circumferentially surrounds the first isolation layer. Multiple second bit line structures are provided on a first side of the first bit line in a third direction and the multiple second bit line structures are arranged at intervals in the second direction, each of the second bit line structures is coupled to the first bit line structure through one select transistor. A staircase structure is provided on a second side of the first bit line in the third direction, and multiple conductive stairs of the staircase structure are respectively coupled to corresponding first bit lines. By providing the staircase structure and the second bit line structure on two sides of the first bit line structure and making the first bit line structure adopt a structure in which the first bit line surrounds the first isolation layer, when the staircase structure is manufactured, the first isolation layer can be configured for blocking to avoid disconnection of a portion of the first bit line located on a side of the first isolation layer close to the second bit line structure, ensuring consistency of the portion of the first bit line, thereby ensuring connection performance with the second bit line structure and improving performance of the memory.

According to some embodiments, the present disclosure further provides an electronic device, including the memory as described above and a processor coupled to the memory. The electronic device has the foregoing memory because the memory has at least an advantage of good storage performance. For details, please refer to the foregoing, and details are not described herein again.

According to some embodiments, the present disclosure further provides a manufacturing method for a memory, including: forming a stacked structure on a substrate, the stacked structure including a first dielectric layer and a second dielectric layer alternately arranged in sequence in a first direction; removing a portion of the stacked structure to form a first trench and multiple second trenches, the first trench extending in a second direction, the multiple second trenches being located on a first side of the first trench in a third direction and arranged at intervals in the second direction, and any two of the second direction, the third direction, and the first direction intersecting each other; removing a portion of the first dielectric layer exposed by the first trench and the second trench to form multiple first accommodation grooves communicated with the first trench and multiple second accommodation grooves communicated with the second trench; and forming a first bit line structure in the first trench and the first accommodation groove, forming a second bit line structure in the second trench and the second accommodation groove, and forming a staircase structure, the first bit line structure including a first isolation layer and a first bit line circumferentially surrounding the first isolation layer, the first bit line being correspondingly located in the first accommodation groove, and the staircase structure being located on a second side of the first bit line in the third direction.

In some possible implementations, the forming a first bit line structure in the first trench and the first accommodation groove, forming a second bit line structure in the second trench and the second accommodation groove, and forming a staircase structure includes: depositing an initial conductive layer, the initial conductive layer being filled in the first accommodation groove and the second accommodation groove, and covering a sidewall and a bottom wall of the first trench and a sidewall and a bottom wall of the second trench; retaining the initial conductive layer located in the first accommodation groove and the second accommodation groove, removing the remaining initial conductive layer, and the initial conductive layer located in the first accommodation groove forming the first bit line; depositing an initial isolation layer, the initial isolation layer filling the remaining first trench and the remaining second trench, the initial isolation layer located in the first trench forming the first isolation layer, and the initial conductive layer located in the second accommodation groove and the initial isolation layer located in the second trench forming the second bit line structure; and forming the staircase structure, the staircase structure including multiple conductive stairs, and the multiple conductive stairs being respectively coupled to corresponding first bit lines.

In some possible implementations, the manufacturing method further includes: etching the first dielectric layer and the second dielectric layer to form a first hole, a second hole, a third hole, and a fourth hole, the first hole being located between the first bit line and the second bit line structure, the second hole being located on two opposite sides of the second bit line structure in the second direction, the third hole being located on a side that is of the second hole and that is away from the second bit line structure, the fourth hole being located on a first side of the first bit line in the third direction, and in the second direction, the fourth hole being opposite to the first hole, and at least one fourth hole being provided between two adjacent first holes; and forming a selection transistor, an access transistor, a capacitor, and a filling pattern, the selection transistor being located in the first hole and coupled to the second bit line structure, the access transistor being located in the second hole and coupled to both the second bit line structure and the first bit line, the capacitor being located in the third hole and coupled to the access transistor, and the filling pattern being located in the fourth hole.

In some possible implementations, the access transistor and the selection transistor are formed synchronously.

In some possible implementations, the forming a staircase structure includes: etching the first dielectric layer and the second dielectric layer that are located on a side that is of the first bit line and that is away from the second bit line structure to form a groove, the groove exposing the first bit lines, two opposite sidewalls in the second direction being both stair-shaped, a stair surface of one sidewall including surfaces that are of remaining odd-numbered second dielectric layers and that face away from the substrate other than a second dielectric layer adjacent to the substrate, and a stair surface of the other sidewall including surfaces that are of even-numbered second dielectric layers and that face away from the substrate; etching to remove a portion of the first dielectric layer exposed by the groove to form a third accommodation groove, each of the first bit lines being correspondingly exposed by the third accommodation groove; forming conductive stairs, the conductive stairs being filled in the third accommodation grooves and in contact with the corresponding first bit lines, and the conductive stairs forming a staircase structure; and forming a third isolation layer in the groove, the third isolation layer filling the groove.

The manufacturing method for a memory provided in the embodiments of the present disclosure have at least the following advantages:

In the manufacturing method of a memory provided in the embodiments of the present disclosure, a stacked structure is formed on a substrate, and a portion of the stacked structure is removed to form a first trench and multiple second trenches. The multiple second trenches are located on a first side of the first trench in a third direction and arranged at intervals in a second direction. A portion of the first dielectric layer exposed by the first trench and the second trench is removed to form multiple first accommodation grooves communicated with the first trench and multiple second accommodation grooves communicated with the second trench. A first bit line structure is formed in the first trench and the first accommodation groove, a second bit line structure is formed in the second trench and the second accommodation groove, and a staircase structure is formed. The first bit line structure includes a first isolation layer and a first bit line circumferentially surrounding the first isolation layer. The first bit line is correspondingly located in the first accommodation groove, and the staircase structure is located on a second side of the first bit line in the third direction and includes multiple conductive stairs. The multiple conductive stairs are respectively coupled to corresponding first bit lines. By providing the staircase structure and the second bit line structure on two sides of the first bit line structure and making the first bit line structure adopt a structure in which the first bit line surrounds the first isolation layer, when the staircase structure is manufactured, the first isolation layer can be configured for blocking to avoid disconnection of a portion of the first bit line located on a side of the first isolation layer close to the second bit line structure, ensuring consistency of the portion of the first bit line, thereby ensuring connection performance with the second bit line structure and improving performance of the memory.

### BRIEF DESCRIPTION OF DRAWINGS

FIG. 1 is a schematic diagram of a structure of a memory according to an embodiment of the present disclosure;

FIG. 2 is an architecture diagram of a first bit line structure, a second bit line structure, and a selection transistor according to an embodiment of the present disclosure;

FIG. 3 is a simplified diagram of an architecture of a memory according to an embodiment of the present disclosure;

FIG. 4 is a schematic diagram of a staircase structure according to an embodiment of the present disclosure;

FIG. 5 is another schematic diagram of a staircase structure according to an embodiment of the present disclosure;

FIG. 6 is still another schematic diagram of a staircase structure according to an embodiment of the present disclosure;

FIG. 7 is a flowchart of a manufacturing method for a memory according to an embodiment of the present disclosure;

FIG. 8 is a three-dimensional schematic diagram of a substrate and a stacked structure according to an embodiment of the present disclosure;

FIG. 9 is a schematic plan diagram of a substrate and a stacked structure according to an embodiment of the present disclosure;

FIG. 10 is a three-dimensional schematic diagram after forming a first mask layer according to an embodiment of the present disclosure;

FIG. 11 is a cross-sectional view taken along line A-A in FIG. 9;

FIG. 12 is a three-dimensional schematic diagram after forming a first trench and second trenches according to an embodiment of the present disclosure;

FIG. 13 is a process diagram of forming a second accommodation groove according to an embodiment of the present disclosure;

FIG. 14 is a schematic diagram of forming a first accommodation groove according to an embodiment of the present disclosure;

FIG. 15 is a process diagram of forming second bit lines and a second isolation layer according to an embodiment of the present disclosure;

FIG. 16 is a process diagram of forming first bit lines and a first isolation layer according to an embodiment of the present disclosure;

FIG. 17 is a three-dimensional schematic diagram after forming a second mask layer according to an embodiment of the present disclosure;

FIG. 18 is a three-dimensional schematic diagram of a schematic diagram after etching one first dielectric layer according to an embodiment of the present disclosure;

FIG. 19 is a three-dimensional schematic diagram after forming a photoresist layer according to an embodiment of the present disclosure;

FIG. 20 is a three-dimensional schematic diagram after etching two first dielectric layers downward according to an embodiment of the present disclosure;

FIG. 21 is a three-dimensional schematic diagram after an opening of a photoresist layer is expanded according to an embodiment of the present disclosure;

FIG. 22 is a three-dimensional schematic diagram after further etching two first dielectric layers downward according to an embodiment of the present disclosure;

FIG. 23 is a process diagram of forming a third accommodation groove according to an embodiment of the present disclosure;

FIG. 24 is a process diagram of forming conductive stairs and a third isolation layer according to an embodiment of the present disclosure;

FIG. 25 is a process diagram of forming a third hole according to an embodiment of the present disclosure;

FIG. 26 is a process diagram of forming an initial electrode layer and a third dielectric layer according to an embodiment of the present disclosure;

FIG. 27 is a process diagram of forming a second electrode layer according to an embodiment of the present disclosure;

FIG. 28 is a process diagram of forming a capacitor dielectric layer according to an embodiment of the present disclosure;

FIG. 29 is a schematic diagram after forming a first electrode according to an embodiment of the present disclosure;

FIG. 30 is a process diagram of forming a first hole according to an embodiment of the present disclosure;

FIG. 31 is a process diagram of forming and exposing an initial active layer according to an embodiment of the present disclosure; and

FIG. 32 is a process diagram of forming an active layer according to an embodiment of the present disclosure.

### DESCRIPTIONS OF REFERENCE NUMERALS

10. Bit line functional group; 11. First bit line 12. First bit line; structure;
13. First isolation layer; 14. Second bit line 15. Second bit line; structure;
16. Second isolation layer; 17. Selection transistor; 18. Filling pattern;
20. Storage unit; 21. Access transistor; 22. Capacitor;
23. Capacitor plug; 30. Staircase structure; 31. Conductive stairs;
32. First segment; 33. Second segment; 34. Bit line plug;
35. Third isolation layer; 40. Substrate; 50. Stacked structure;
51. First dielectric layer; 52. Second dielectric 53. First trench; layer;
54. Second trench; 55. First 56. Second accommodation accommodation groove; groove;
61. Gate; 62. Gate dielectric 63. Active layer; layer;
71. First mask layer; 72. Second mask layer; 73. Photoresist layer;
81. Third hole; 82. Initial electrode 83. Third dielectric layer; layer;
84. Second electrode; 85. Capacitor dielectric 86. First electrode; layer;
87. First hole; 88. Initial active layer; 91. Groove;
92. Third accommodation 93. Fourth 94. Fifth groove; accommodation accommodation groove; and groove.

### DESCRIPTION OF EMBODIMENTS

To make the foregoing objects, features, and advantages of the embodiments of the present disclosure clearer and easier to understand, the technical solutions in the embodiments of the present disclosure are clearly described below with reference to the accompanying drawings in the embodiments of the present disclosure. Clearly, the described embodiments are merely some rather than all of the embodiments of the present disclosure. Based on the embodiments of the present disclosure, all other embodiments obtained by a person of ordinary skill in the art without creative efforts fall within the protection scope of the present disclosure.

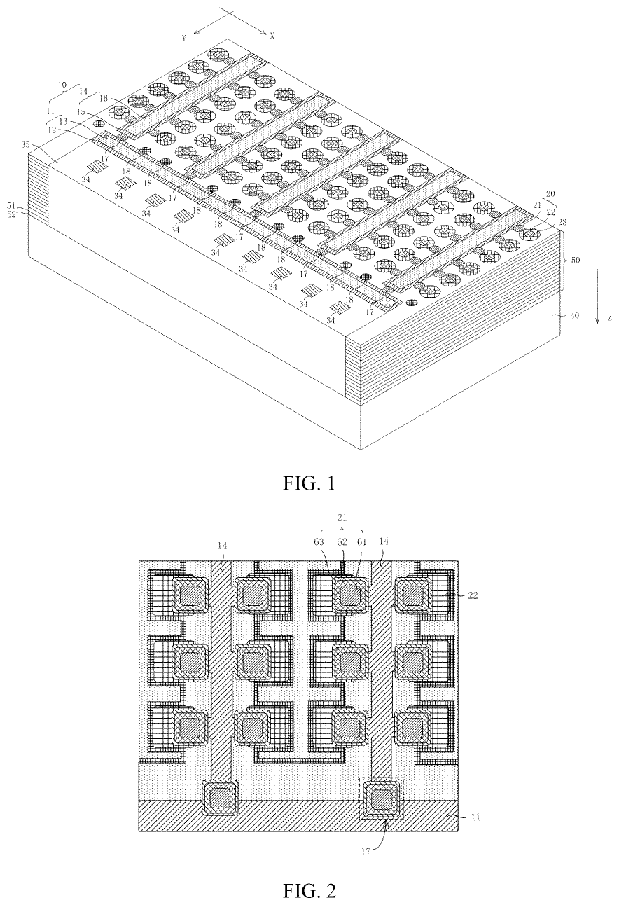

Referring to FIG. 1 to FIG. 6, the embodiments of the present disclosure provide a memory, and the memory may be a dynamic random access memory. The memory includes multiple bit line functional groups 10, multiple storage units 20, and a staircase structure 30. The bit line functional groups 10 are connected to corresponding storage units 20 to read or write data from or to the corresponding storage units 20. The multiple storage units 20 are configured to store data, and the staircase structure 30 is configured to externally connect the multiple bit line functional groups 10.

The multiple bit line functional groups 10 are arranged at intervals in a first direction, and the first direction is the Z direction shown in FIG. 1. Each of the bit line functional groups 10 includes a first bit line structure 11, multiple second bit line structures 14, and multiple selection transistors 17. The multiple second bit line structures 14 are located on a side of the first bit line structure 11, and the first bit line structure 11 is coupled to the multiple second bit line structures 14 to serve as a common bit line, thereby aggregating the multiple second bit line structures 14. Each of the second bit line structures 14 is coupled to a corresponding storage unit 20, and the selection transistor 17 is configured to gate one of the second bit line structures 14. It may be understood that first bit line structures 11 in the multiple bit line functional groups 10 are opposite in the first direction, and second bit line structures 14 in the multiple bit line functional groups 10 are opposite in the first direction.

In some possible examples, the first bit line structure 11 includes a first isolation layer 13 and a first bit line 12, the first isolation layer 13 extends in a second direction, the second direction intersects the first direction, and the second direction is the X direction shown in FIG. 1. The first bit line 12 circumferentially surrounds the first isolation layer 13. For example, the first bit line 12 circumferentially surrounds the first isolation layer 13 in an all-round manner, that is, the first bit line 12 is in a closed ring shape, which surrounds the first isolation layer 13 for an entire cycle. Multiple second bit line structures 14 are provided on a first side of the first bit line 12 in a third direction, where the third direction intersects both the second direction and the first direction, that is, any two of the third direction, the second direction, and the first direction intersect each other, for example, are perpendicular to each other. The third direction is the Y direction shown in FIG. 1, and the first side of the first bit line 12 in the third direction is the upper side shown in FIG. 2.

With such an arrangement, two opposite sides of the first isolation layer 13 in the third direction both have a portion of the first bit line 12. When other structures are manufactured on one side in two opposite sides of the first bit line 12 in the third direction, for example, when a staircase structure 30 is manufactured on a second side of the first bit line 12 in the third direction, the first isolation layer 13 can be configured for blocking to avoid disconnection of the first bit line 12 on the other side, thereby ensuring consistency of the first bit line 12 on the other side and connection performance with other structures.

In the third direction, the thickness of the first isolation layer 13 may be greater than the thickness of the first bit line 12. For example, the first isolation layer 13 includes a first sub-isolation layer extending in the second direction, and a second sub-isolation layer surrounding the first sub-isolation layer. The material of the first sub-isolation layer is different from the material of the second sub-isolation layer. The material of the thicker first sub-isolation layer may be an oxide, such as silicon oxide, aluminium oxide, or the like, and the material of the thinner second sub-isolation layer may be a nitride, such as silicon nitride, silicon oxynitride, silicon carbide nitride, or the like.

In some possible implementations, the first bit line 12 in at least one of the bit line functional groups 10 includes a first bit line portion and a second bit line portion, and the first bit line portion is in the non-closed ring shape. For example, the first bit line 12 in each of the bit line functional groups 10 includes a first bit line portion and a second bit line portion. Alternatively, first bit lines 12 in a portion of the bit line functional groups 10 each include a first bit line portion and a second bit line portion that are in the non-closed ring shape (for example, the portion of the bit line functional groups are generally far away from a substrate 40), and first bit lines 12 in a remaining portion of the bit line functional groups 10 are in a closed ring shape (for example, this portion of the bit line functional groups are generally close to the substrate 40), that is, first bit line portions in the remaining bit line functional groups 10 each include a first bit line portion that is in a closed ring shape.

In an example in which the first bit line 12 includes the first bit line portion and the second bit line portion, the first bit line portion is in the non-closed ring shape, and an opening of the non-closed ring shape is located on a second side of the first bit line structure 11 in the third direction. In some examples, the opening of the first bit line portion is formed in a manufacturing procedure of the staircase structure 30. The second bit line portion is located at the opening of the non-closed ring shape. For example, the second bit line portion fills the opening, and the first bit line portion and the second bit line portion are connected end to end to form a closed ring shape surrounding the first isolation layer 13.

It may be understood that an opening is formed between two ends of the first bit line portion, the first bit line portion is continuous on a side that is of the first isolation layer 13 and that faces the second bit line structure 14, and two ends of the first bit line portion are both located on a side that is of the first isolation layer 13 and that is facing away from the second bit line structure 14. The first bit line portion is coupled to the second bit line structures 14 to ensure that the second bit line structures 14 are all connected to a portion of the first bit line 12 having the same material composition, thereby ensuring consistency of connection performance between the second bit line structures 14 and the first bit line 12.

Still referring to FIG. 1, the multiple second bit line structures 14 are located on the first side of the first bit line 12 in the third direction. For example, in the second direction, two ends of the first bit line 12 both correspondingly protrude beyond two outermost second bit line structures 14, so that multiple second bit lines 15 are coupled to the first bit line 12. The multiple second bit line structures 14 all extend in the third direction and are arranged at intervals in the second direction.

In some possible examples, the second bit line structure 14 includes a second isolation layer 16 extending in the third direction and a second bit line 15 circumferentially surrounding the second isolation layer 16. For example, the second bit line 15 circumferentially surrounds the second isolation layer 16 in an all-round manner, that is, the second bit line 15 is in a closed ring shape. In the third direction, the thickness of the second isolation layer 16 may be greater than the thickness of the second bit line 15. The second isolation layer 16 has the same material composition as the first isolation layer 13, that is, the second isolation layer 16 and the first isolation layer 13 have the same structure, and film layers corresponding thereto have the same material.

It may be understood that the first isolation layer 13 has at least two film layers, and the second isolation layer 16 also has the same quantity of film layers. An arrangement manner of film layers of the first isolation layer 13 is the same as an arrangement manner of film layers of the second isolation layer 16, and film layers at corresponding positions of the first isolation layer 13 and the second isolation layer 16 have the same material. For example, the first isolation layer 13 includes a first sub-isolation layer and a second sub-isolation layer, and the second sub-isolation layer surrounds the first sub-isolation layer. Correspondingly, the second isolation layer 16 includes a third sub-isolation layer and a fourth sub-isolation layer, and the fourth sub-isolation layer surrounds the third sub-isolation layer. The first sub-isolation layer has the same material as the third sub-isolation layer, and the second sub-isolation layer has the same material as the fourth sub-isolation layer.

First bit lines 12 in some of the bit line functional groups 10 each include a first bit line portion and a second bit line portion, and the first bit line portion and the second bit line portion have different material compositions. First bit lines 12 in remaining bit line functional groups 10 each include only a first bit line portion. The first bit line portions in the remaining bit line functional groups 10 are a whole first bit line 12, and the second bit line 15 and the first bit line portion have the same material composition. The second bit line 15 and the first bit line portion have the same structure, and film layers corresponding thereto have the same material.

In some possible examples, first isolation layers 13 that are opposite in the first direction are connected to form an integral structure, and first bit lines 12 that are opposite in the first direction are spaced apart from each other to facilitate manufacturing of the first isolation layer 13. It may be understood that the first isolation layer 13 is columnar, the axis direction of which is the first direction, and taking a plane perpendicular to the axis direction as a cross section, a cross-sectional shape of the first isolation layer 13 is a strip shape. In the axial direction, multiple first bit lines 12 that are spaced apart are sleeved on an outer peripheral surface of the first isolation layer 13.

In some possible examples, second isolation layers 16 that are opposite in the first direction are connected to form an integral structure, and second bit lines 15 that are opposite in the first direction are spaced apart from each other to facilitate manufacturing of the second isolation layer 16. It may be understood that the second isolation layer 16 is columnar, the axis direction of which is the first direction, and taking a plane perpendicular to the axis direction as a cross section, a cross-sectional shape of the second isolation layer 16 is a strip shape. In the axial direction, multiple second bit lines 15 that are spaced apart are sleeved on an outer peripheral surface of the second isolation layer 16.

Referring to FIG. 1 to FIG. 3, multiple selection transistors 17 are located between the first bit line structure 11 and the multiple second bit line structures 14, and each of the second bit line structures 14 is coupled to the first bit line structure 11 through one selection transistor 17. Specifically, the multiple selection transistors 17 are arranged at intervals in the second direction, and one selection transistor 17 is correspondingly provided on a side that is of each of the second bit line structures 14 and that is opposite to the first bit line structure 11. The second bit line 15 in the second bit line structure 14 is coupled to the corresponding selection transistor 17, and the first bit line 12 in the first bit line structure 11 is coupled to the corresponding selection transistor 17.

The multiple storage units 20 are arranged at intervals in the first direction, arranged at intervals in the second direction, and arranged at intervals in the third direction. Each of the second bit line structures 14 is correspondingly provided with a storage unit 20 on at least one side in two opposite sides of the each of the second bit line structures 14 in the second direction, and the storage unit 20 is coupled to the corresponding second bit line structure 14. For example, a storage unit 20 is provided on each side in two opposite sides of each of the second bit line structures 14 in the second direction, so as to improve storage density of the memory. Storage units 20 on sides that are of two adjacent second bit line structures 14 and that are adjacent to each other are spaced apart.

As shown in FIG. 1, each of the storage units 20 includes an access transistor 21 and a capacitor 22 that are coupled. The access transistor 21 is correspondingly coupled to the second bit line structure 14, for example, to the second bit line 15. The capacitor 22 is disposed on a side, away from the corresponding second bit line structure 14, of the access transistor 21.

In some possible implementations, the selection transistor 17 and the access transistor 21 each include a gate 61, a gate dielectric layer 62 surrounding the gate 61, and an active layer 63 surrounding the gate dielectric layer 62, that is, the access transistor 21 is a channel all around (Channel All Around, CAA for short) transistor. Gates 61 that are opposite in the first direction are connected to form a word line, that is, the word line extends in the first direction. Gate dielectric layers 62 that are opposite in the first direction are connected to form an integrated structure, and active layers 63 that are opposite in the first direction are spaced apart from each other and coupled to the corresponding second bit line structures 14. The material of the active layer 63 may be indium gallium zinc oxide (Indium Gallium Zinc Oxide, IGZO for short) to improve performance such as electron mobility of the active layer 63.

In some possible implementations, the capacitor 22 includes a first electrode, a capacitor dielectric layer surrounding the first electrode, and a second electrode surrounding the capacitor dielectric layer. First electrodes that are opposite in the first direction are connected to form an integral structure, capacitor dielectric layers that are opposite in the first direction are connected to form an integral structure, and second electrodes that are opposite in the first direction are spaced apart from each other and coupled to the corresponding active layers 63. Multiple first electrodes are connected together to form a first electrode column, a filling hole extending in the first direction is further disposed in the first electrode column, and the filling hole is filled with a capacitor plug 23.

Still referring to FIG. 1, the memory further includes multiple filling patterns 18, and the multiple filling patterns 18 are located on a first side of the first bit line 12 in the third direction. That is, the multiple filling patterns 18 and the multiple selection transistors 17 are located on the same side of the first bit line 12. In the second direction, the multiple filling patterns 18 are opposite to the multiple selection transistors 17. For example, the multiple filling patterns 18 and the multiple selection transistors 17 form a row in the second direction. At least one of the filling patterns 18 is provided between two adjacent selection transistors 17, which can improve uniformity of overall arrangement of the selection transistors 17, the access transistors 21, and the filling patterns 18, and reduce loading effect of etching during manufacturing.

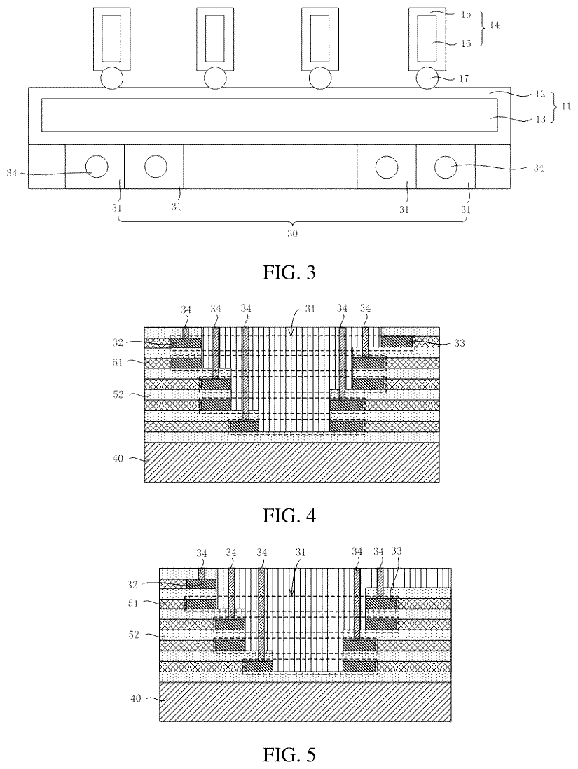

Still referring to FIG. 3, the staircase structure 30 is located on a second side of the first bit line 12 in the third direction, that is, the staircase structure 30 and the multiple second bit line structures 14 are respectively located on two sides of the first bit line 12. The staircase structure 30 includes multiple conductive stairs 31, and the multiple conductive stairs 31 are respectively coupled to first bit lines 12 in the multiple bit line functional groups 10. That is, one first bit line 12 is connected to at least one (for example, one) conductive stair 31, so as to externally connect the first bit line 12.

In an example in which the first bit line 12 in at least one bit line functional group 10 includes the first bit line portion and the second bit line portion, the second bit line portion and the conductive stair 31 have the same material composition. The second bit line portion may be formed synchronously with the conductive stair 31. That is, when the conductive stair 31 is formed, a material configured to form the conductive stair 31 further fills at least a portion of an opening of the first bit line portion, and this portion of material forms the second bit line portion.

In some possible implementations, referring to FIG. 4 and FIG. 5, each of the conductive stairs 31 has a groove, and the groove separates the corresponding conductive stair 31 into a first segment 32 and a second segment 33 that are spaced apart in the second direction. The grooves are communicated, and each of the grooves has a first end and a second end that are opposite in the second direction. The first end of each of the grooves may be the left end shown in FIG. 4, and the second end of each of the grooves may be the right end shown in FIG. 4.

In any three adjacent grooves in the first direction, a first end of a groove located in the middle is opposite to a first end of one of remaining two grooves, a second end of the groove located in the middle is opposite to a second end of the other of the remaining two grooves. That is, a staircase structure 30 is formed in the middle of the conductive stair 31. Specifically, as shown in FIG. 4, two adjacent first segments 32 in multiple first segments 32 are aligned toward one end of the second segment 33, or two adjacent second segments 33 in multiple second segments 33 are aligned toward one end of the first segment 32, so that first segments 32 every other row form a first staircase, second segments 33 every other row form a second staircase, and stair surfaces of the first staircase and stair surfaces of the second staircase are staggered in the first direction, and the first staircase and the second staircase form a staircase structure 30.

For example, there are five conductive stairs 31. For convenience of description, the five conductive stairs 31 are sequentially defined as a first conductive stair, a second conductive stair, a third conductive stair, a fourth conductive stair, and a fifth conductive stair. The first conductive stair is located at the top, and the fifth conductive stair is located at the bottom.

As shown in FIG. 4, a first segment 32 of the fourth conductive stair faces one end (the right end shown in FIG. 4) of a second segment 33 of the fourth conductive stair, and is aligned with one end (the right end shown in FIG. 4) that is of a first segment 32 of the third conductive stair and that faces a second segment 33 of the third conductive stair. A first segment 32 of the second conductive stair faces one end (the right end shown in FIG. 4) of a second segment 33 of the second conductive stair, and is aligned with one end that is of a first segment 32 of the first conductive stair and that faces a second segment 33 of the first conductive stair. A first segment 32 of the fifth conductive stair, the first segment 32 of the third conductive stair, and the first segment 32 of the first conductive stair form a first staircase, and the first staircase is configured to externally connect a first bit line 12 opposite to the fifth conductive stair, a first bit line 12 opposite to the third conductive stair, and a first bit line 12 opposite to the first conductive stair (for example, through the bit line plug 34 in FIG. 4).

A second segment 33 of the fifth conductive stair faces one end (the left end shown in FIG. 4) of the first segment 32 of the fifth conductive stair, and is aligned with one end (the left end shown in FIG. 4) that is of the second segment 33 of the fourth conductive stair and that faces the first segment 32 of the fourth conductive stair. The second segment 33 of the third conductive stair faces one end (the left end shown in FIG. 4) of the first segment 32 of the third conductive stair, and is aligned with one end (the left end shown in FIG. 4) that is of the second segment 33 of the second conductive stair and that faces the first segment 32 of the second conductive stair. The second section 33 of the fourth conductive stair and the second section 33 of the second conductive stair form a second staircase, and the second staircase is configured to externally connect a first bit line 12 opposite to the fourth conductive stair and a first bit line 12 opposite to the second conductive stair (for example, through the bit line plug 34 in FIG. 4).

Based on the foregoing implementations, in some examples, referring to FIG. 5, a non-aligned end of the uppermost groove may further extend to an end portion of a corresponding conductive stair 31.

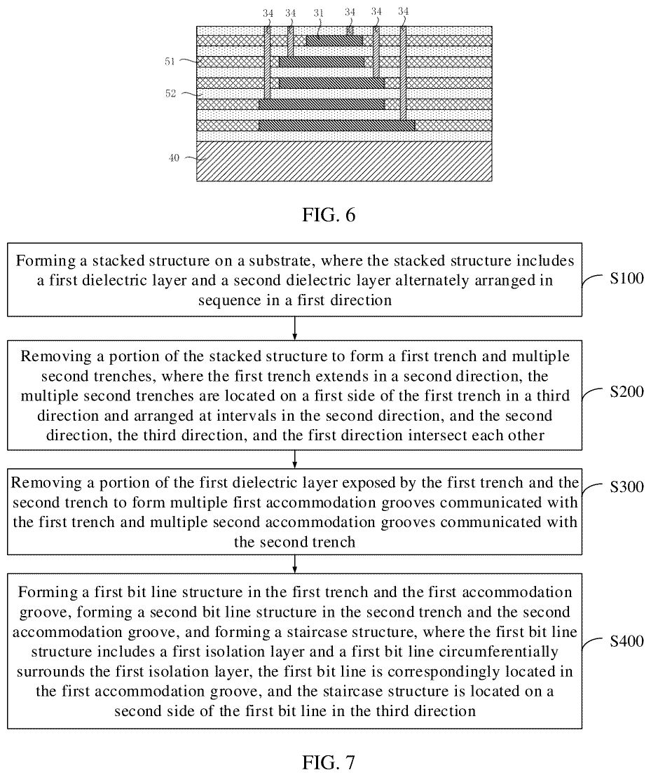

In some other possible implementations, referring to FIG. 6, each of the conductive stairs 31 has a first end and a second end that are opposite in the second direction. In any three adjacent conductive stairs 31 in the first direction, a first end of a conductive stair 31 located in the middle is opposite to a first end of one of remaining two conductive stairs 31, a second end of the conductive stair 31 located in the middle is opposite to a second end of the other of the remaining two conductive stairs 31, so as to form a staircase structure 30. That is, two ends of the conductive stairs 31 form a staircase structure 30 to reduce difference in signal transmission resistance.

For example, there are five conductive stairs 31. For convenience of description, the five conductive stairs 31 are sequentially defined as a first conductive stair, a second conductive stair, a third conductive stair, a fourth conductive stair, and a fifth conductive stair. The first conductive stair is located at the top, and the fifth conductive stair is located at the bottom.

A first end of the fifth conductive stair is aligned with a first end of the fourth conductive stair, and a second end of the fifth conductive stair protrudes beyond a second end of the fourth conductive stair. The second end of the fourth conductive stair is aligned with a second end of the third conductive stair, and the first end of the fourth conductive stair protrudes beyond a first end of the second conductive stair. A first end of the third conductive stair is aligned with the first end of the second conductive stair, and the second end of the third conductive stair protrudes beyond a second end of the second conductive stair. The second end of the second conductive stair is aligned with a second end of the first conductive stair, and the first end of the second conductive stair protrudes beyond a first end of the first conductive stair.

The first end of the fourth conductive stair and the first end of the second conductive stair form a first staircase, and the first staircase is configured to externally connect a first bit line 12 opposite to the fourth conductive stair and a first bit line 12 opposite to the second conductive stair. The second end of the fifth conductive stair, the second end of the third conductive stair, and the second end of the first conductive stair form a second staircase, and the second staircase is configured to externally connect a first bit line 12 opposite to the fifth conductive stair, a first bit line 12 opposite to the third conductive stair, and a first bit line 12 opposite to the first conductive stair.

In still some other possible implementations, each of the conductive stairs 31 has a first end and a second end that are opposite in the second direction. In the first direction, in two adjacent conductive stairs 31, a first end of the lower conductive stair 31 protrudes beyond a first end of the upper conductive stair 31, and a second end of the lower conductive stair 31 protrudes beyond a second end of the upper conductive stair 31. First ends of conductive stairs 31 in odd-numbered rows form a first staircase, and second ends of conductive stairs 31 in even-numbered rows form a second staircase, so as to form a staircase structure 30.

In summary, the memory in the embodiments of this application includes multiple bit line functional groups 10, multiple storage units 20, and a staircase structure 30, and the multiple bit line functional groups 10 are arranged at intervals in the first direction. Each of the bit line functional groups 10 includes a first bit line structure 11, multiple second bit line structures 14, and multiple selection transistors 17. The first bit line structure 11 includes a first isolation layer 13 and a first bit line 12, the first isolation layer 13 extends in the second direction, and the first bit line 12 circumferentially surrounds the first isolation layer 13. Multiple second bit line structures 14 are provided on a first side of the first bit line 12 in the third direction and the multiple second bit line structures 14 are arranged at intervals in the second direction, and each of the second bit line structures 14 is coupled to the first bit line structure 11 through one selection transistor 17. A staircase structure 30 is provided on a second side of the first bit line 12 in the third direction, and multiple conductive stairs 31 of the staircase structure 30 are respectively coupled to corresponding first bit lines 12. By providing the staircase structure 30 and the second bit line structure 14 on two sides of the first bit line structure 11 and making the first bit line structure 11 adopt a structure in which the first bit line 12 surrounds the first isolation layer 13, when the staircase structure 30 is manufactured, the first isolation layer 13 can be configured for blocking to avoid disconnection of a portion of the first bit line 12 located on a side of the first isolation layer 13 close to the second bit line structure 14, ensuring consistency of the portion of the first bit line 12, thereby ensuring connection performance with the second bit line structure 14 and improving performance of the memory.

The embodiments of this application further provide an electronic device, which includes a memory and a processor coupled to the memory. For the memory, reference may be made to the foregoing. The processor may be a central processing unit (Central Processing Unit, CPU for short), or may be another general-purpose processor, a digital signal processor (Digital Signal Processor, DSP for short), an application-specific integrated circuit (Application Specific Integrated Circuit, ASIC for short), or the like. The general-purpose processor may be a microprocessor, or the processor may be any conventional processor or the like.

The electronic device in the embodiments of this application includes the foregoing memory, and thus has at least an advantage that a portion of the first bit line 12 on a side close to the second bit line structure 14 is not easily disconnected and has good storage performance. For a specific effect, reference may be made to the foregoing, and details are not described herein again.

Referring to FIG. 7, the embodiments of this application provide a manufacturing method for a memory. The manufacturing method specifically includes the following steps:

In step S100, a stacked structure is formed on a substrate, where the stacked structure includes a first dielectric layer and a second dielectric layer alternately arranged in sequence in a first direction.

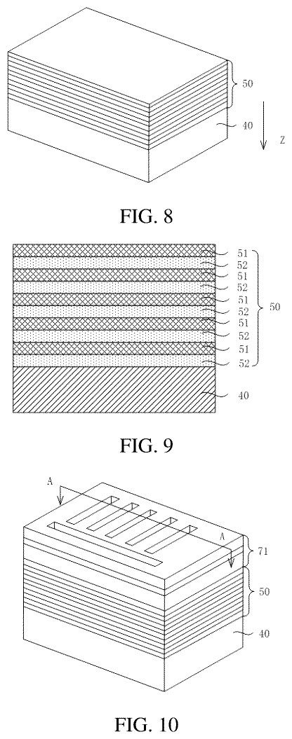

Referring to FIG. 8 and FIG. 9, a substrate 40 may be a silicon substrate, a germanium substrate, a silicon carbide substrate, a silicon germanium substrate, a germanium on insulator (Germanium on Insulator, GOI for short) substrate, a silicon on insulator (Silicon on Insulator, SOI for short) substrate, or the like. A stacked structure 50 is formed on the substrate 40, and the stacked structure 50 includes a first dielectric layer 51 and a second dielectric layer 52 alternately arranged in sequence in the first direction. The first direction is the Z direction shown in FIG. 8. In some examples, the second dielectric layer 52 is disposed on the substrate 40, the material of the second dielectric layer 52 may be an oxide, such as silicon oxide, and the material of the first dielectric layer 51 may be a nitride, such as silicon nitride or silicon oxynitride.

In step S200, a portion of the stacked structure is removed to form a first trench and multiple second trenches, where the first trench extends in a second direction, the multiple second trenches are located on a first side of the first trench in a third direction and arranged at intervals in the second direction, and the second direction, the third direction, and the first direction intersect each other.

Referring to FIG. 10 to FIG. 12, a portion of the stacked structure 50 is removed to form a first trench 53 and multiple second trenches 54 in the stacked structure 50. The first trench 53 and the multiple second trenches 54 expose the substrate 40. For example, the first trench 53 and the multiple second trenches 54 run through the stacked structure 50, and bottoms of the trenches are located in the substrate 40. The first trench 53 extends in the second direction, and the second direction and the first direction intersect, for example, are perpendicular. Multiple second trenches 54 are formed on a first side of the first trench 53 in the third direction.

The multiple second trenches 54 all extend in the third direction and are arranged at intervals in the second direction. The third direction intersects with the second direction and the first direction, that is, any two of the third direction, the second direction, and the first direction intersect with each other, for example, are perpendicular to each other. The second direction is the X direction shown in FIG. 12, and the third direction is the Y direction shown in FIG. 12.

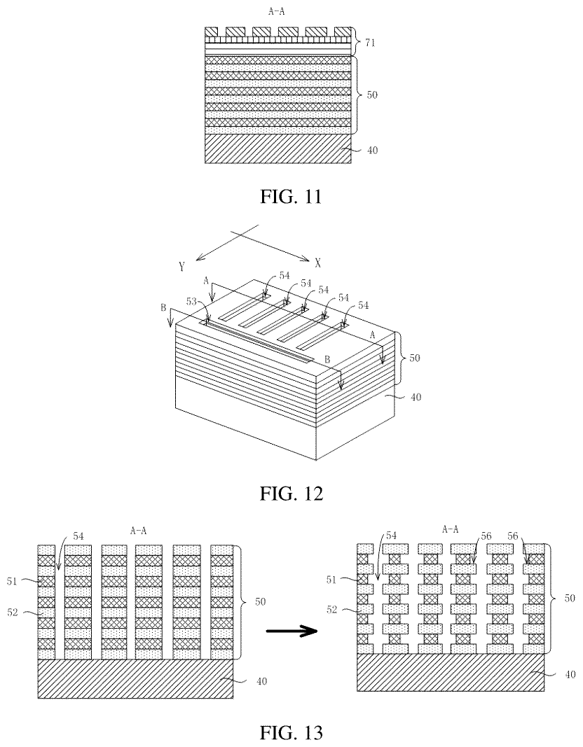

The multiple second trenches 54 and the first trench 53 may be simultaneously formed by adopting an etching process. As shown in FIG. 11 and FIG. 12, a first mask layer 71 is formed on the stacked structure 50, and the first mask layer 71 has a preset pattern. The first mask layer 71 is used as a mask, and the exposed stacked structure 50 is etched and removed to form the second trenches 54 and the first trench 53. The remaining first mask layer 71 is then removed.

In step S300, a portion of the first dielectric layer exposed by the first trench and the second trench is removed to form multiple first accommodation grooves communicated with the first trench and multiple second accommodation grooves communicated with the second trench.

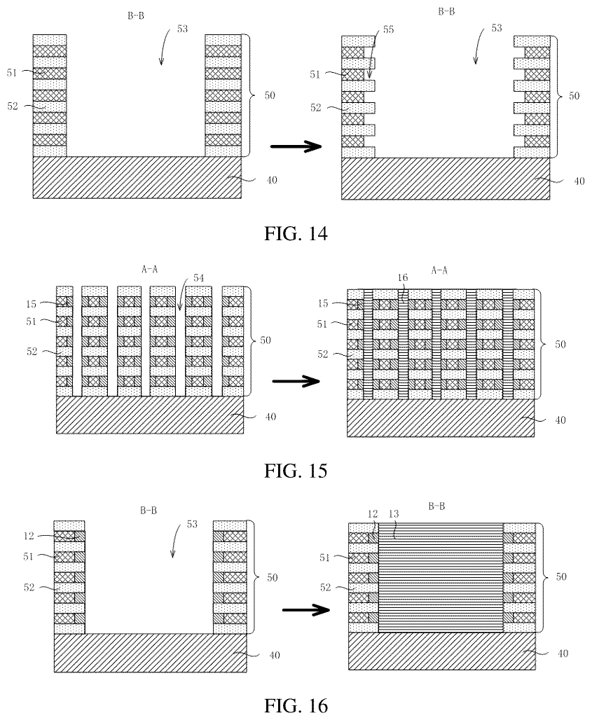

Referring to FIG. 13 and FIG. 14, a portion of the first dielectric layer 51 exposed by the first trench 53 is removed to form multiple first accommodation grooves 55. The multiple first accommodation grooves 55 circumferentially surround the first trench 53 in an all-round manner and are communicated with the first trench 53, and the multiple first accommodation grooves 55 are spaced apart from each other in the first direction. In addition, a portion of the second dielectric layer 52 exposed by the second trench 54 is removed to form multiple second accommodation grooves 56. The multiple second accommodation grooves 56 circumferentially surround the second trench 54 in an all-round manner and are communicated with the second trench 54. The multiple second accommodation grooves 56 are spaced apart from each other in the first direction. The second accommodation grooves 56 and the first accommodation grooves 55 may be formed synchronously.

In step S400, a first bit line structure is formed in the first trench and the first accommodation groove, a second bit line structure is formed in the second trench and the second accommodation groove, and a staircase structure 30 is formed; and the first bit line structure includes a first isolation layer and a first bit line circumferentially surrounds the first isolation layer, the first bit line is correspondingly located in the first accommodation groove, and the staircase structure 30 is located on a second side of the first bit line in the third direction.

Referring to FIG. 15, FIG. 16, and FIG. 1, a first bit line structure 11 is formed in the first trench 53 and the first accommodation groove 55, and the first bit line structure 11 includes a first isolation layer 13 and a first bit line 12. The first isolation layer 13 extends in the second direction, and the first bit line 12 circumferentially surrounds the first isolation layer 13, for example, the first bit line 12 circumferentially surrounds the first isolation layer 13 in an all-round manner. The first isolation layer 13 is integrated in the first direction, the first bit lines 12 are correspondingly located in the first accommodation grooves 55, and the first bit lines 12 are spaced apart from each other in the first direction.

In some possible examples, the first bit line 12 fills the first accommodation groove 55, that is, the first bit line 12 is in a closed ring shape, an inner surface of the first bit line 12 is aligned with a sidewall of the first trench 53, and the first isolation layer 13 is correspondingly filled in the first trench 53. In some other possible examples, the first bit line 12 fills a portion that is of the first accommodation groove 55 and that is away from the first trench 53, that is, the first bit line 12 fills the bottom of the first accommodation groove 55, the first isolation layer 13 fills the first trench 53, and a portion of the first accommodation groove 55 adjacent to the first trench 53, and the first bit line 12 and a portion of the first isolation layer 13 fill the first trench 53. In still some other possible examples, the first bit line 12 fills the first accommodation groove 55 and protrudes beyond the first accommodation groove 55, that is, the first bit line 12 extends into the first trench 53, and the first isolation layer 13 fills remaining first trench 53.

The staircase structure 30 is located on a second side of the first bit line 12 in the third direction, that is, the staircase structure 30 and multiple second bit line structures 14 are respectively located on two sides of the first bit line 12. The staircase structure 30 includes multiple conductive stairs 31, and the multiple conductive stairs 31 are arranged at intervals in the first direction, and are respectively coupled to corresponding first bit lines 12, so as to externally connect the first bit lines 12. The conductive stairs 31 are disposed at the same layer as the second dielectric layer 52.

In summary, in the manufacturing method for a memory in the embodiments of this application, a stacked structure 50 is formed on a substrate 40, and a portion of the stacked structure 50 is removed to form a first trench 53 and multiple second trenches 54, where the multiple second trenches 54 are located on a first side of the first trench 53 in the third direction, and are arranged at intervals in the second direction. A portion of the first dielectric layer 51 exposed by the first trench 53 and the second trench 54 is removed to form multiple first accommodation grooves 55 communicated with the first trench 53 and multiple second accommodation grooves 56 communicated with the second trench 54. A first bit line structure 11 is formed in the first trench 53 and the first accommodation groove 55, a second bit line structure 14 is formed in the second trench 54 and the second accommodation groove 56, and a staircase structure 30 is formed. The first bit line structure 11 includes a first isolation layer 13 and a first bit line 12 circumferentially surrounding the first isolation layer 13. The first bit line 12 is correspondingly located in the first accommodation groove 55, and the staircase structure 30 is located on a second side of the first bit line 12 in the third direction and includes multiple conductive stairs 31. The multiple conductive stairs 31 are respectively coupled to corresponding first bit lines 12. By providing the staircase structure 30 and the second bit line structure 14 on two sides of the first bit line structure 11 and making the first bit line structure 11 adopt a structure in which the first bit line 12 surrounds the first isolation layer 13, when the staircase structure 30 is manufactured, the first isolation layer 13 can be configured for blocking to avoid disconnection of a portion of the first bit line 12 on a side of the first isolation layer 13 close to the second bit line structure 14, ensuring consistency of the portion of the first bit line 12, thereby ensuring connection performance with the second bit line structure 14 and improving performance of the memory.

In some possible examples, that a first bit line structure 11 is formed in the first trench 53 and the first accommodation groove 55, a second bit line structure 14 is formed in the second trench 54 and the second accommodation groove 56, and a staircase structure 30 is formed (step of S400) includes the following steps:

In step S101, an initial conductive layer is deposited, where the initial conductive layer is filled in the first accommodation groove 55 and the second accommodation groove 56, and covers a sidewall and a bottom wall of the first trench 53 and a sidewall and a bottom wall of the second trench 54.

An initial conductive layer is deposited in the first accommodation groove 55, the second accommodation groove 56, the first trench 53, and the second trench 54. The initial conductive layer is filled in the first accommodation groove 55 and the second accommodation groove 56, covers a sidewall and a bottom wall of the first trench 53, and covers a sidewall and a bottom wall of the second trench 54, but does not fill the first trench 53 and the second trench 54.

For example, the initial conductive layer includes an initial first conductive layer and an initial second conductive layer. The initial first conductive layer covers a sidewall and a bottom wall of the first accommodation groove 55, a sidewall and a bottom wall of the second accommodation groove 56, a sidewall and a bottom wall of the first trench 53, and a sidewall and a bottom wall of the second trench 54, and the initial second conductive layer covers the initial first conductive layer and fills remaining first accommodation grooves 55 and second accommodation grooves 56. The material of the initial first conductive layer may be titanium nitride, and the material of the initial second conductive layer may be tungsten.

In step S102, the initial conductive layer located in the first accommodation groove 55 and the second accommodation groove 56 is retained, the remaining initial conductive layer is removed, and the initial conductive layer located in the first accommodation groove 55 forms the first bit line 12.

The initial conductive layer is etched, the initial conductive layer located in the first accommodation groove 55 and the second accommodation groove 56 is retained, and the remaining initial conductive layer is removed, so as to form the first bit line 12. There are multiple first bit lines 12, and the multiple first bit lines 12 are located in corresponding accommodation grooves 55. The multiple first bit lines 12 are isolated from each other in the first direction.

In step S103, an initial isolation layer is deposited, the initial isolation layer fills remaining first trenches 53 and remaining second trenches 54, the initial isolation layer located in the first trench 53 forms the first isolation layer 13, and the initial conductive layer located in the second accommodation groove 56 and the initial isolation layer located in the second trench 54 form the second bit line structure 14.

An initial isolation layer is deposited within remaining first trenches 53 and second trenches 54 to fill the first trench 53 and the second trench 54. The initial isolation layer located in the first trench 53 forms a first isolation layer 13, and the first isolation layer 13 is continuous in the first direction. The initial conductive layer located in the second accommodation groove 56 forms a second bit line 15. There are multiple second bit lines 15, and the multiple second bit lines 15 are located in corresponding second accommodation grooves 56. The multiple second bit lines 15 are isolated from each other in the first direction. The initial isolation layer located in the second trench 54 forms a second isolation layer 16, and the second isolation layer 16 is continuous in the first direction. The second isolation layer 16 and the second bit line 15 form a second bit line structure 14, that is, the second bit line structure 14 and the first bit line structure 11 may be formed synchronously, thereby reducing times of etching and deposition and simplifying a manufacturing procedure.

In step S104, a staircase structure 30 is formed, where the staircase structure 30 includes multiple conductive stairs 31, and the multiple conductive stairs 31 are respectively coupled to corresponding first bit lines 12.

The staircase structure 30 and the multiple second bit line structures 14 are respectively located on two sides of the first bit line 12. The staircase structure 30 includes multiple conductive stairs 31, and the multiple conductive stairs 31 are arranged at intervals in the first direction, and are respectively coupled to corresponding first bit lines 12, so as to externally connect the first bit lines 12.

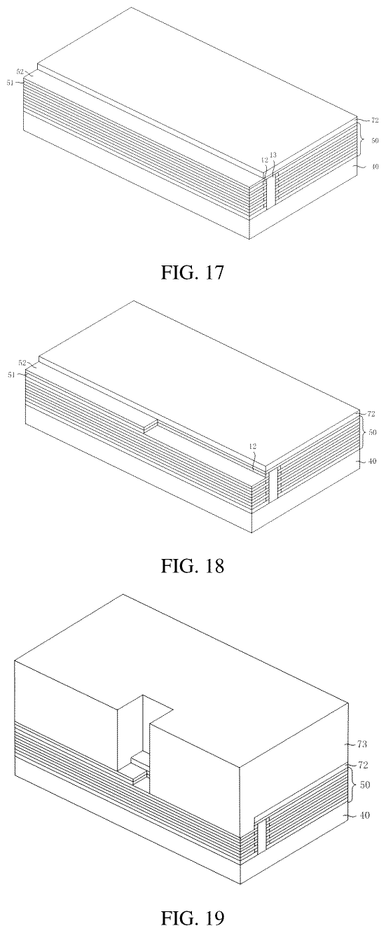

In some possible implementations, referring to FIG. 17 to FIG. 24, that a staircase structure 30 is formed (step of S104) specifically includes the following steps:

In step S1041, the first dielectric layer 51 and the second dielectric layer 52 on a side that is of the first bit line 12 and that is away from the second bit line structure 14 are etched to form a groove 91, where the groove 91 exposes the first bit lines 12, two opposite sidewalls in the second direction are both stair-shaped, a stair surface of one sidewall includes surfaces that are of remaining odd-numbered second dielectric layers 52 and that face away from the substrate 40 other than a second dielectric layer 52 adjacent to the substrate 40, and a stair surface of the other sidewall includes surfaces that are of even-numbered second dielectric layers 52 and that face away from the substrate 40.

The groove 91 exposes a partial region of each of the first bit lines 12, and the two opposite sidewalls of the groove 91 in the second direction are both stair-shaped. Both the left sidewall and the right sidewall of the groove 91 are stair-shaped. A stair surface of one of two sidewalls of the groove 91 includes surfaces that are of remaining odd-numbered second dielectric layers 52 and that face away from the substrate 40 other than a second dielectric layer 52 adjacent to the substrate 40, and a stair surface of the other of two sidewalls of the groove 91 includes surfaces that are of even-numbered second dielectric layers 52 and that face away from the substrate 40.

For example, in a direction away from the substrate 40, surfaces that are of a 3rd second dielectric layer 52, . . . , a (2n+1)-th second dielectric layer 52 and that face away from the substrate 40 form a stair surface of one sidewall of the groove 91, and surfaces that are of a 2nd second dielectric layer 52, . . . , a 2n-th second dielectric layer 52 and that face away from the substrate 40 form a stair surface of the other sidewall of the groove 91, and n is a positive integer greater than 1.

As shown in FIG. 17 to FIG. 22, the groove 91 may be formed through the following procedures:

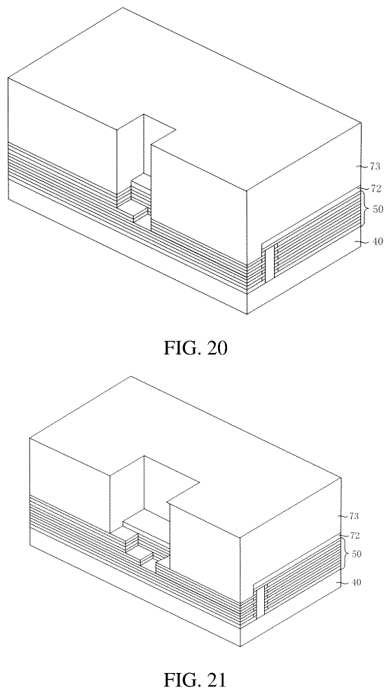

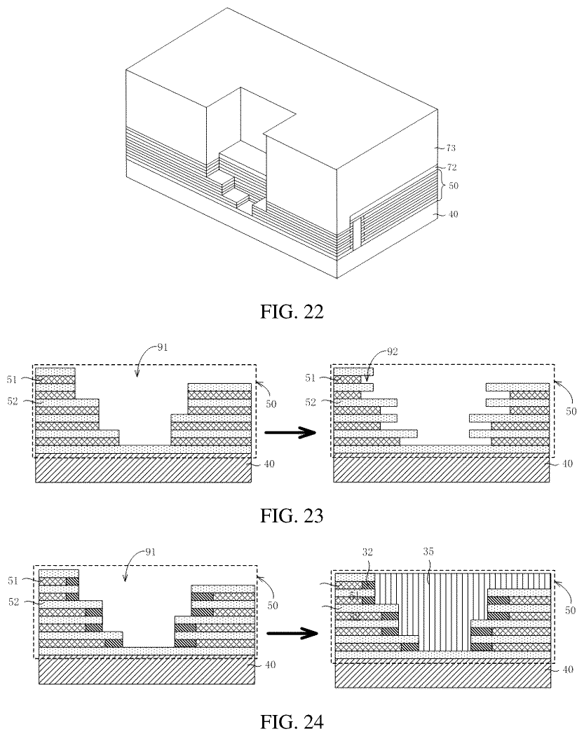

Referring to FIG. 17, a second mask layer 72 is formed on the stacked structure 50, and the second mask layer 72 includes a second side of the first bit line. Referring to FIG. 18, portions of a second dielectric layer 52 and a first dielectric layer 51 on the second side of the first bit line 12 that are farthest from the substrate 40 are etched and removed to expose the second dielectric layer 52 below the first dielectric layer 51 and the first bit line 12 farthest from the substrate 40, thereby forming two stair surfaces. Referring to FIG. 19, a photoresist layer 73 is formed. The photoresist layer 73 has an opening, and the opening exposes portions of the two stair surfaces. Referring to FIG. 20, the photoresist layer 73 is taken as a mask, and portions of two second dielectric layers 52 and two corresponding first dielectric layers 51 are etched downward and removed, so that the two original stair surfaces extend downward, and two new stair surfaces are formed. Referring to FIG. 21, the opening of the photoresist layer 73 is enlarged, and a photoresist layer 73 with an enlarged opening is taken as a mask to continue etching downward to remove portions of two second dielectric layers 52 and corresponding two first dielectric layers 51, so as to extend the original four stair surfaces downward to form two new stair surfaces. The previous step is repeated until etching reaches a second dielectric layer 52 closest to the substrate 40, or until etching reaches the substrate 40, as shown in FIG. 22.

In step S1042, a portion of the first dielectric layer 51 exposed by the groove 91 is etched and removed to form a third accommodation groove 92, and each of the first bit lines 12 is correspondingly exposed by the third accommodation groove 92.

Referring to FIG. 23, portions of sidewalls of the groove 91 are etched to remove a portion of the first dielectric layer 51, forming multiple third accommodation grooves 92 arranged at intervals in the first direction, and the first bit lines 12 are correspondingly exposed by the third accommodation grooves 92. In some examples, during formation of the groove 91, the exposed first bit line 12 may be etched, or even the exposed portion of some first bit lines 12 may be completely removed (a remaining portion is a first bit line portion), exposing the first isolation layer 13. The groove 91 and the third accommodation grooves 92 are located on one side of the first isolation layer 13, and the first isolation layer 13 can serve as a barrier layer to avoid disconnection of the first bit line 12 on the other side of the first isolation layer 13, thereby ensuring that the second bit line structures 14 are connected to the same structure and ensuring reliability and consistency of connection.

In step S1043, conductive stairs 31 are formed, where the conductive stairs 31 are filled in the third accommodation grooves 92 and in contact with the corresponding first bit lines 12, and the conductive stairs 31 form a staircase structure 30.

Referring to FIG. 23 and FIG. 24, conductive stairs 31 are deposited in the third accommodation grooves 92, and the conductive stairs 31 are spaced apart from each other in the first direction and in corresponding contact with the first bit lines 12. The conductive stair 31 may be formed by means of deposition and etching back, and may fill the third accommodation groove 92. While the conductive stair 31 is formed, the material of the conductive stair 31 further fills a removed portion of the first bit line (that is, a second bit line portion is formed). The conductive stairs 31 form a staircase structure 30, so as to implement external connection of the first bit lines 12.

In step S1044, a third isolation layer 35 is formed in the groove 91, and the third isolation layer 35 fills the groove.

Referring to FIG. 24 and FIG. 5, the third isolation layer 35 may include a nitride layer that conformally covers the staircase structure 30 and an oxide layer that fills the remaining groove 91. Bit line plugs 34 are formed in the third isolation layer 35, and the bit line plugs 34 are in corresponding contact with the conductive stairs 31, so as to implement external connection of the corresponding first bit lines 12.

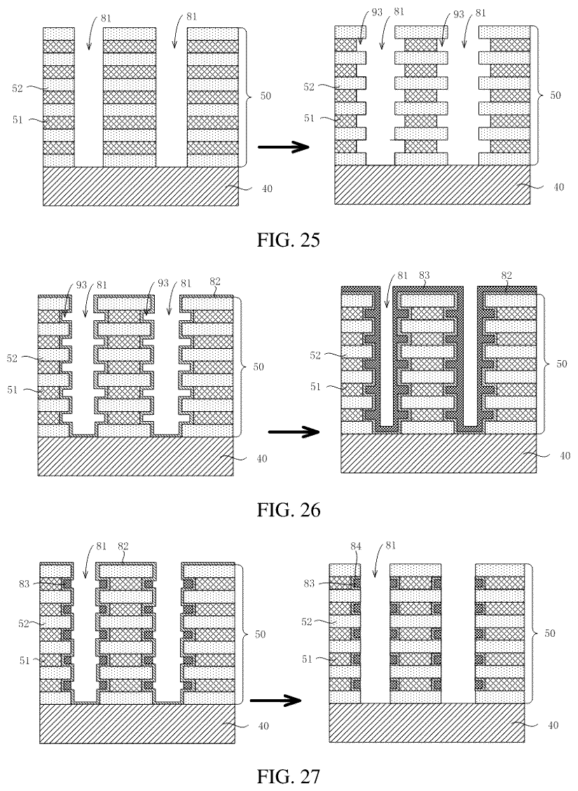

In some possible examples, referring to FIG. 25 to FIG. 32, the manufacturing method further includes the following steps:

In step a, the first dielectric layer 51 and the second dielectric layer 52 are etched to form a first hole, a second hole, a third hole, and a fourth hole; and the first hole is located between the first bit line 12 and the second bit line structure 14, the second hole is located on two opposite sides of the second bit line structure 14 in the second direction, the third hole is located on a side that is of the second hole and that is away from the second bit line structure 14, the fourth hole is located on a first side of the first bit line 12 in the third direction, and in the second direction, the fourth hole is opposite to the first hole, and at least one fourth hole is provided between two adjacent first holes.

The first hole, the second hole, the third hole, and the fourth hole can run through the first dielectric layer 51 and the second dielectric layer 52, where the first hole is located on a first side of the first bit line 12 in the second direction, is on the same side as the second bit line structure 14, and is located on a side that is of the second hole and that is adjacent to the first bit line 12. Multiple second holes are provided on two opposite sides of the second bit line structure 14 in the second direction, and the multiple second holes are spaced apart in the third direction. The third hole is located on a side that is of the second bit line structure 14 and that is away from the second bit line structure 14. The fourth hole is on the same side as the first hole and is located in the same row as the first hole in the second direction. For example, the first hole and the fourth hole are distributed at equal intervals as a whole.

With such an arrangement, the first hole, the second hole, the third hole, and the fourth hole are evenly distributed, which reduces loading effect when the first hole, the second hole, the third hole, and the fourth hole are formed through etching. It may be understood that this step may be performed before step S200, and the sequence is not limited.

In step b, a selection transistor 17, an access transistor 21, a capacitor 22, and a filling pattern 18 are formed, where the selection transistor 17 is located in the first hole and coupled to both the second bit line structure 14 and the first bit line 12, the access transistor 21 is located in the second hole and coupled to the second bit line structure 14, the capacitor 22 is located in the third hole and coupled to the access transistor 21, and the filling pattern 18 is located in the fourth hole.

The access transistor 21 and the selection transistor 17 are formed synchronously to simplify a manufacturing procedure. The material of the filling pattern 18 may be aluminium oxide. The access transistor and the selection transistor 17 each include a gate 61, a gate dielectric layer 62 surrounding the gate 61, and an active layer 63 surrounding the gate dielectric layer 62. Gates 61 that are opposite in the first direction are connected to form a word line, that is, the word line extends in the first direction. Gate dielectric layers 62 that are opposite in the first direction are connected to form an integrated structure, and active layers 63 that are opposite in the first direction are spaced apart from each other and coupled to the corresponding second bit line structures 14. The material of the active layer 63 may be indium gallium zinc oxide to improve migration performance of the active layer 63.

The capacitor 22 includes a first electrode, a capacitor dielectric layer surrounding the first electrode, and a second electrode surrounding the capacitor dielectric layer. First electrodes that are opposite in the first direction are connected to form an integral structure, capacitor dielectric layers that are opposite in the first direction are connected to form an integral structure, and second electrodes that are opposite in the first direction are spaced apart from each other and coupled to the corresponding active layers 63. Multiple first electrodes are connected together to form a first electrode column, a filling hole extending in the first direction is further disposed in the first electrode column, and the filling hole is filled with a capacitor plug 23.

It may be understood that a manufacturing sequence of the access transistor, the selection transistor 17, the capacitor 22, and the filling pattern 18 is not limited, and a manufacturing sequence of other structures is not limited. For example, a manufacturing procedure of the access transistor and the selection transistor 17 may be performed in parallel with a manufacturing procedure of the first bit line structure 11 and the second bit line structure 14.

In some possible implementations, the first hole, the second hole, the third hole, and the fourth hole are formed synchronously. After the first hole, the second hole, the third hole, and the fourth hole are formed, a filling material is formed in the first hole, the second hole, the third hole, and the fourth hole, and the filling material located in the fourth hole forms the filling pattern 18.

In some possible implementations, referring to FIG. 25 to FIG. 29, the capacitor 22 may be manufactured through the following procedures:

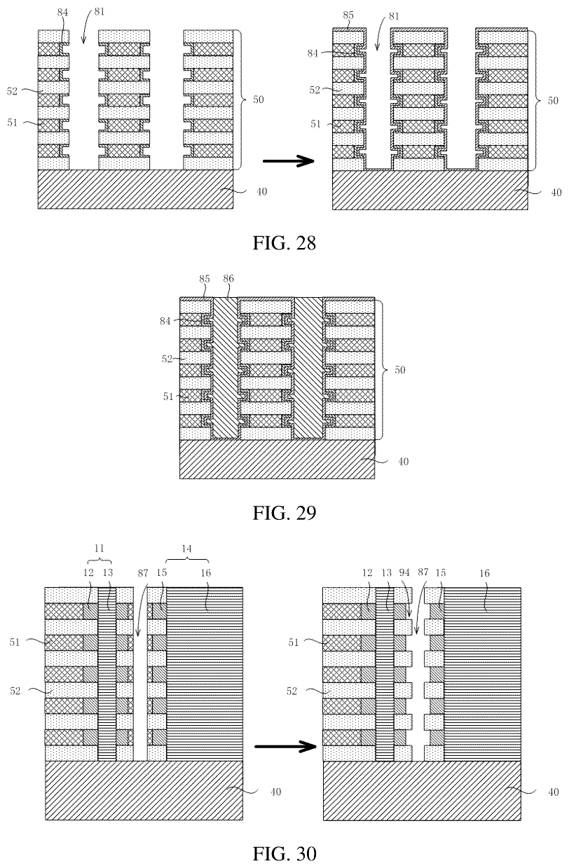

Referring to FIG. 25, a filling material in a third hole 81 is removed to expose the third hole 81. The first dielectric layer 51 exposed by the third hole 81 is then laterally etched to form a fourth accommodation groove 93, so as to enlarge the third hole 81. Referring to FIG. 26, an initial electrode layer 82 is formed on a sidewall of the fourth accommodation groove 93 and a sidewall and a bottom wall of the third hole 81, and a third dielectric layer 83 covering the initial electrode layer 82 is formed, where the initial electrode layer 82 does not fill the fourth accommodation groove 93, and the third dielectric layer 83 fills the fourth accommodation groove 93. Referring to FIG. 26, the third dielectric layer 83 outside the fourth accommodation groove 93 is removed to expose a portion of the initial electrode layer 82. The exposed initial electrode layer 82 is removed to form multiple second electrodes 84 spaced apart, and then the remaining third dielectric layer 83 is removed. Referring to FIG. 28, a capacitor dielectric layer 85 is formed in the third hole 81 and the fourth accommodation groove 93, where the capacitor dielectric layer 85 covers the second electrode 84, and then, a first electrode 86 is formed in the remaining third hole 81 and fourth accommodation groove 93.

In some possible implementations, referring to FIG. 30 to FIG. 32, the selection transistor 17 may be specifically manufactured through the following procedures:

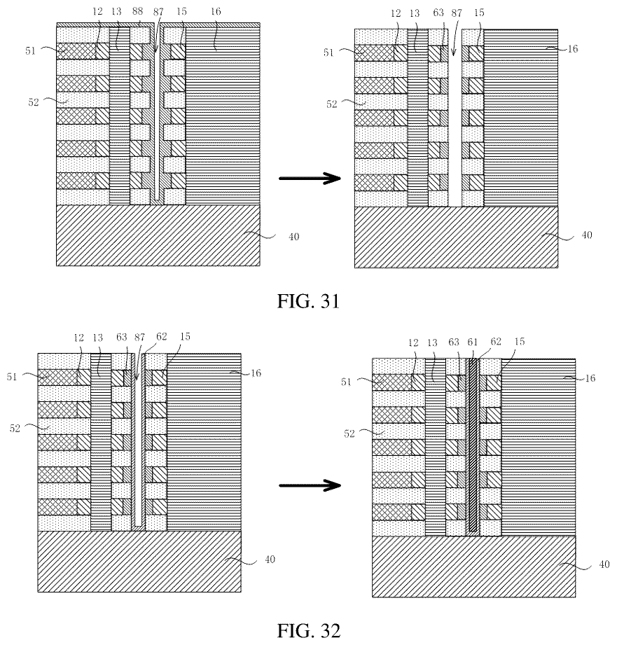

Referring to FIG. 30, the filling pattern in the third hole 81 is removed to expose the first hole 87. The first dielectric layer 51 exposed by the first hole 87 is then laterally etched to form a fifth accommodation groove 94, and the fifth accommodation groove 94 exposes a sidewall of the first bit line 12 and a sidewall of the second bit line 15. Referring to FIG. 31, an initial active layer 88 is formed on a sidewall of the fifth accommodation groove 94 and on a sidewall and a bottom wall of the first hole 87, and the initial active layer 88 fills the fifth accommodation groove 94. Then, referring to FIG. 32, the initial active layer 88 on a sidewall of the second dielectric layer 52 is etched and removed, and the initial active layer 88 in the fifth accommodation groove 94 is retained, so as to form multiple active layers 63. A gate dielectric layer 62 that conformally covers the active layer 63 is then formed in the first hole 87, and a gate 61 (that is, a word line) is formed in the remaining first hole 87.

For manufacturing of the access transistor 21, reference may be made to the manufacturing of the selection transistor 17. In manufacturing procedures of the access transistor 21, the sidewall of the corresponding second bit line 15 and the second electrode 84 of the capacitor are exposed. Other manufacturing procedures are similar to those of the selection transistor 17, and details are not described herein again.

The embodiments and the implementations in this specification are described in a progressive manner. Each embodiment focuses on a difference from other embodiments. Refer to the embodiments for same or similar parts in the embodiments. Descriptions with reference to terms “one embodiment”, “some embodiments”, “example implementation”, “example”, “specific example”, “some examples”, or the like means that specific features, structures, materials, or characteristics described with reference to implementations or examples are included in at least one implementation or example of the present disclosure. In this specification, a schematic description of the foregoing term does not necessarily refer to the same implementation or an example. Further, specific features, structures, materials, or characteristics described may be properly combined in any one or more implementations or examples.

Finally, it should be noted that the foregoing embodiments are merely intended for describing the technical solutions of the present disclosure, but not for limiting the present disclosure. Although the present disclosure is described in detail with reference to the foregoing embodiments, persons of ordinary skill in the art should understand that they may still make modifications to the technical solutions described in the foregoing embodiments or make equivalent replacements to some or all technical features thereof. However, these modifications or replacements do not make the essence of the corresponding technical solutions depart from the scope of the technical solutions in the embodiments of the present disclosure.

What is claimed is:

1. A memory, comprising: a plurality of bit line functional groups arranged at intervals in a first direction, a plurality of storage units, and a staircase structure;
each of the bit line functional groups comprising:
a first bit line structure, the first bit line structure comprising a first isolation layer extending in a second direction and a first bit line circumferentially surrounding the first isolation layer;
a plurality of second bit line structures, the plurality of second bit line structures being located on a first side of the first bit line in a third direction and arranged at intervals in the second direction, each of the second bit line structures comprising a second bit line, and any two of the second direction, the third direction, and the first direction intersecting each other; and
a plurality of selection transistors, the plurality of selection transistors being located between the first bit line structure and the plurality of second bit line structures, and the second bit lines in the plurality of second bit line structures being respectively coupled to the first bit line through the plurality of selection transistors; and
the plurality of storage units being respectively coupled to corresponding second bit lines, the staircase structure being located on a second side of the first bit line in the third direction and comprising a plurality of conductive stairs, and the plurality of conductive stairs being respectively coupled to first bit lines in the plurality of bit line functional groups.

2. The memory according to claim 1, wherein the first bit line in at least one of the bit line functional groups comprises a first bit line portion and a second bit line portion, the first bit line portion is in a non-closed ring shape, an opening of the non-closed ring shape is located on a second side of the first bit line structure in the third direction, the second bit line portion is located at the opening of the non-closed ring shape, and the second bit line portion has a same material composition as the conductive stairs.

3. The memory according to claim 2, wherein first bit lines in some of the bit line functional groups each comprise the first bit line portion and the second bit line portion, and first bit lines in remaining bit line functional groups are each in a closed ring shape; and
each of the second bit line structures further comprises a second isolation layer extending in the third direction, and the second bit line circumferentially surrounds the second isolation layer.

4. The memory according to claim 3, wherein the second isolation layer has a same material composition as the first isolation layer, and the first bit line portion has a same material composition as the second bit line.

5. The memory according to claim 3, wherein first isolation layers that are opposite in the first direction are connected to form an integral structure, and first bit lines that are opposite in the first direction are spaced apart from each other; and
second isolation layers that are opposite in the first direction are connected to form an integral structure, and second bit lines that are opposite in the first direction are spaced apart from each other.

6. The memory according to claim 1, wherein the plurality of storage units are arranged at intervals in the first direction, arranged at intervals in the second direction, and arranged at intervals in the third direction, and each of the second bit line structures is correspondingly provided with the storage unit on at least one side in two opposite sides of the each of the second bit line structures in the second direction.

7. The memory according to claim 6, wherein each of the storage units comprises an access transistor and a capacitor that are coupled, the access transistor is correspondingly coupled to the second bit line structure, and the capacitor is disposed on a side, away from the corresponding second bit line structure, of the access transistor.

8. The memory according to claim 7, wherein the selection transistor and the access transistor each comprise a gate, a gate dielectric layer surrounding the gate, and an active layer surrounding the gate dielectric layer; and
gates that are opposite in the first direction are connected to form a word line, gate dielectric layers that are opposite in the first direction are connected to form an integrated structure, and active layers that are opposite in the first direction are spaced apart from each other and coupled to the corresponding second bit line structures.

9. The memory according to claim 7, wherein the capacitor comprises a first electrode, a capacitor dielectric layer surrounding the first electrode, and a second electrode surrounding the capacitor dielectric layer; and
first electrodes that are opposite in the first direction are connected to form an integral structure, capacitor dielectric layers that are opposite in the first direction are connected to form an integral structure, and second electrodes that are opposite in the first direction are spaced apart from each other and coupled to the corresponding active layers.

10. The memory according to claim 1, wherein each of the conductive stairs has a groove, the groove separates the corresponding conductive stair into a first segment and a second segment that are spaced apart in the second direction, the grooves are communicated, and each of the grooves has a first end and a second end that are opposite in the second direction; and
in any three adjacent grooves in the first direction, a first end of a groove located in a middle is opposite to a first end of one of remaining two grooves, a second end of the groove located in the middle is opposite to a second end of the other of the remaining two grooves, so that first segments in every other row form a first staircase, second segments in every other row form a second staircase, stair surfaces of the first staircase and stair surfaces of the second staircase are staggered in the first direction, and the first staircase and the second staircase form the staircase structure.

11. The memory according to claim 1, wherein each of the conductive stairs has a first end and a second end that are opposite in the second direction; and
in any three adjacent conductive stairs in the first direction, a first end of a conductive stair located in a middle is opposite to a first end of one of remaining two conductive stairs, a second end of the conductive stair located in the middle is opposite to a second end of the other of the remaining two conductive stairs, so that first ends of conductive stairs in every other row form a first staircase, second ends of conductive stairs in every other row form a second staircase, stair surfaces of the first staircase and stair surfaces of the second staircase are staggered in the first direction, and the first staircase and the second staircase form the staircase structure.

12. The memory according to claim 1, wherein the memory further comprises a plurality of filling patterns located on a first side of the first bit line in the third direction, and in the second direction, the plurality of filling patterns are opposite to the plurality of selection transistors, and at least one of the filling patterns is provided between two adjacent selection transistors.

13. An electronic device, comprising: the memory according to claim 1, and a processor coupled to the memory.

14. A manufacturing method for a memory, comprising:
forming a stacked structure on a substrate, the stacked structure comprising a first dielectric layer and a second dielectric layer alternately arranged in sequence in a first direction;
removing a portion of the stacked structure to form a first trench and a plurality of second trenches, the first trench extending in a second direction, the plurality of second trenches being located on a first side of the first trench in a third direction and arranged at intervals in the second direction, and any two of the second direction, the third direction, and the first direction intersecting each other;
removing a portion of the first dielectric layer exposed by the first trench and the second trench to form a plurality of first accommodation grooves communicated with the first trench and a plurality of second accommodation grooves communicated with the second trench; and
forming a first bit line structure in the first trench and the first accommodation groove, forming a second bit line structure in the second trench and the second accommodation groove, and forming a staircase structure, the first bit line structure comprising a first isolation layer and a first bit line circumferentially surrounding the first isolation layer, the first bit line being correspondingly located in the first accommodation groove, and the staircase structure being located on a second side of the first bit line in the third direction.

15. The manufacturing method according to claim 14, wherein the forming a first bit line structure in the first trench and the first accommodation groove, forming a second bit line structure in the second trench and the second accommodation groove, and forming a staircase structure comprises:
depositing an initial conductive layer, the initial conductive layer being filled in the first accommodation groove and the second accommodation groove, and covering a sidewall and a bottom wall of the first trench and a sidewall and a bottom wall of the second trench;
retaining the initial conductive layer located in the first accommodation groove and the second accommodation groove, removing the remaining initial conductive layer, and the initial conductive layer located in the first accommodation groove forming the first bit line;
depositing an initial isolation layer, the initial isolation layer filling the remaining first trench and the remaining second trench, the initial isolation layer located in the first trench forming the first isolation layer, and the initial conductive layer located in the second accommodation groove and the initial isolation layer located in the second trench forming the second bit line structure; and
forming the staircase structure, the staircase structure comprising a plurality of conductive stairs, and the plurality of conductive stairs being respectively coupled to corresponding first bit lines.

16. The manufacturing method according to claim 14, wherein the manufacturing method further comprises:
etching the first dielectric layer and the second dielectric layer to form a first hole, a second hole, a third hole, and a fourth hole, the first hole being located between the first bit line and the second bit line structure, the second hole being located on two opposite sides of the second bit line structure in the second direction, the third hole being located on a side that is of the second hole and that is away from the second bit line structure, the fourth hole being located on a first side of the first bit line in the third direction, and in the second direction, the fourth hole being opposite to the first hole, and at least one fourth hole being provided between two adjacent first holes; and
forming a selection transistor, an access transistor, a capacitor, and a filling pattern, the selection transistor being located in the first hole and coupled to both the second bit line structure and the first bit line, the access transistor being located in the second hole and coupled to the second bit line structure, the capacitor being located in the third hole and coupled to the access transistor, and the filling pattern being located in the fourth hole.

17. The manufacturing method according to claim 16, wherein the access transistor and the selection transistor are formed synchronously.

18. The manufacturing method according to claim 14, wherein the forming a staircase structure comprises:
etching the first dielectric layer and the second dielectric layer that are located on a side that is of the first bit line and that is away from the second bit line structure to form a groove, the groove exposing the first bit lines, two opposite sidewalls in the second direction being both stair-shaped, a stair surface of one sidewall comprising surfaces that are of remaining odd-numbered second dielectric layers other than a second dielectric layer adjacent to the substrate and that face away from the substrate, and a stair surface of the other sidewall comprising surfaces that are of even-numbered second dielectric layers and that face away from the substrate;
etching to remove a portion of the first dielectric layer exposed by the groove to form a third accommodation groove, each of the first bit lines being correspondingly exposed by the third accommodation groove;
forming conductive stairs, the conductive stairs being filled in the third accommodation grooves and in contact with the corresponding first bit lines, and the conductive stairs forming a staircase structure; and
forming a third isolation layer in the groove, the third isolation layer filling the groove.
